(19) United States
(12) Patent Application Publication
(10) Pub. No.: US 2011/0229806 A1
(43) Pub. Date: Sep. 22, 2011

(54) PHASE MASK AND METHOD OF FABRICATION

(75) Inventors: Yuankun Lin, Denton, TX (US); Karen Lozano, McAllen, TX (US); Ahmad Harb, Zarqa (JO); Daniel Rodriguez Ponce, Celaya (MX)

(73) Assignee: The Board of Regents of The University of Texas System, Austin, TX (US)

(21) Appl. No.: 13/054,363

(22) PCT Filed: Jul. 16, 2009
(86) PCT No.: PCT/US09/50864

§ 371 Date: May 5, 2011

Related U.S. Application Data
(60) Provisional application No. 61/081,226, filed on Jul. 16, 2008.

(51) Int. Cl. G03F 1/00

(52) U.S. Cl. 430/5

(57) ABSTRACT

A method of fabricating a two-layer phase mask comprises subjecting a photoresist material to two overlapping laser beams that create light and dark fringes in the overlapping beam regions. The photoresist can comprise a liquid crystal and a photo-sensitive material, including, for example, a photo-sensitive monomer and/or polymer. The two laser beams can be first directed towards one side of the photoresist. In the areas subjected to lighter fringes, the polymer molecules can link together and force the liquid crystal into the areas subjected to the darker fringes. This can leave an alternating pattern of linear strips of polymer-rich and liquid crystal-rich regions. The exposure time can be limited so that the strips are formed only partially through the thickness of the photoresist. The photoresist can be then rotated 90 degrees and the overlapping laser beams directed towards the opposite side of the photoresist. Alternating strips of polymer-rich and liquid crystal-rich regions can be formed that extend partially through the photoresist. These strips can be arranged orthogonally to the strips formed on the opposite side of the photoresist. The material in liquid crystal-rich regions can be washed out when the photoresist is developed. A two-layer, integrated phase mask can therefore be produced. Exemplary methods eliminate the need for complicated alignment techniques.

### RELATED APPLICATIONS

This application claims priority to Application Ser. No. 61/081,226 filed Jul. 16, 2008, entitled “Phase Mask and Method of Fabrication”, the entire contents of which are herein incorporated by reference.

This invention was made with government support under Grant No. CMMI-0609345 awarded by the National Science Foundation.

### BACKGROUND OF THE INVENTION

I. Field of the Invention

Embodiments of the present invention relate generally to systems and methods relating to phase masks. More specifically, embodiments relate to systems and methods relating to the fabrication of a two-layer integrated phase mask.

II. Description of Related Art

A photonic crystal is a dielectric medium in which periodic microstructures are formed using high refractive index contrast materials. Since its first introduction in 1987, a large number of applications have been proposed using photonic crystal structures. However, it has been a great challenge to rapidly fabricate large-area and defect-free three-dimensional (3D) photonic crystals at low cost. A number of fabrication techniques such as conventional multilayer stacking of woodpile structures using semiconductor fabrication processes, colloidal self-assembly, and multi-photon direct laser writing have been employed to produced sub-micron 3D photonic crystals or templates. Holographic lithography based on multi-beam interference has also been employed to fabricate 3D photonic crystals by exposing a photoresist or polymerizable resin to interference patterns of laser beams. This multi-beam interference technique has produced defect free, nanometerscale structures over large substrate areas. Photonic structures are defined in photoresist by isointensity (iso-laser dosage) surfaces of interference patterns.

A desired geometrical structure could be obtained by single or multiple exposures. The holographic lithography has also been used to produce tunable photonic crystals in a liquid crystal and polymer system, and to demonstrate a chiral microstructure in SU-8 photoresist. In the case of positive resist, the overexposed material is then dissolved away in the post-exposure processing. The underexposed region forms a periodic network and acts as a 3D photonic crystal template. For negative photoresists, the underexposed regions can then be selectively removed using a developer while overexposed region becomes polymerized and forms a periodic network for photonic crystal template. The template can then be infiltrated at room temperature with SiO2 and burned away, leaving behind a daughter “inverse” template. Finally, the daughter template is inverted by infiltration with silicon and selective etching of the SiO2.

However, fabrication strategies that rely on interference of multiple independent beams have introduced optical complexity when a large number of bulk optical components, such as mirrors, beam splitters, and lenses were used to generate multi-beams. In order to improve the optical setup, diffractive optics elements or phase masks have been introduced to create the interference pattern for the holographic fabrication of photonic crystals. When a single beam goes through a diffractive optics element or a phase mask, an interference pattern will be formed behind these optical devices. If designed properly, a single optical element can replace a complex optical setup to generate a desired interference pattern. A simple face-centered-cubic can be achieved with a single exposure through a two-dimensional phase mask. Such structure does not lead to a large photonic band gap.

It has previously been demonstrated that a “woodpile” structure (diamond-like structure) with a large photonic band gap can be fabricated by two independent exposures of the photo-resist through two separate, orthogonal, one-dimensional gratings. However, the alignment of the second exposure with the first exposure was an experimental challenge. An approach has also been proposed for fabricating a photonic crystal template using single-exposure, single-beam, optical interference lithography based on diffraction of light through a single “integrated” optical phase mask consisting of two orthogonally oriented gratings.

Illuminating the phase mask with a normally incident beam produces a five-beam interference pattern which can be used to expose a suitable photoresist and produce a photonic crystal template. However no experimental fabrication of such optical phase mask has been reported to date.

No known method for fabricating an integrated, two-layer phase mask has been developed. Such a method would eliminate the need to align single-layer phase masks to each other, therefore greatly reducing the complexity of fabricating such a mask.

### SUMMARY OF THE INVENTION

Exemplary embodiments of the present disclosure comprise an integrated two-layer phase mask and methods of manufacturing such a mask. In general terms, exemplary embodiments comprise exposing each side of a photoresist material to electromagnetic radiation (e.g., holographic lithography, electronic-beam lithography, or two-photon lithography).

In one specific embodiment, a phase mask is manufactured by providing a photoresist material on a glass slide and utilizing holographic lithography by exposing one side of the photoresist material to two overlapping laser beams that create light and dark fringes in the overlapping beam regions.

In this embodiment, the photoresist material is exposed on one side and the photoresist material (or the pattern emitted from the laser beams) is then rotated 90 degrees. The opposite side of the photoresist material is then also exposed to the overlapping laser beams. The exposure of each side of the photoresist to the electromagnetic radiation is limited so that the radiation does not affect the entire thickness of the photoresist material. In specific embodiments, the photoresist material comprises a liquid crystal and polymer mixture and the electromagnetic radiation exposure creates alternating strips of polymer-rich and liquid crystal-rich strips.

After the photoresist material has been exposed to electromagnetic radiation, the material can be developed to remove the material in the liquid crystal rich regions. The remaining photoresist material forms two layers of alternating strips that are arranged orthogonally from each other.

It is understood that other embodiments may comprise different photoresist materials, including for example, different compositions of materials, and positive or negative resist materials. Other embodiments may also comprise different forms of holographic lithography, including different forms of electromagnetic radiation. Additional embodiments may also comprise other patterns of radiation that are different from the linear strips provided in the disclosed embodiment.

Exemplary embodiments of the present disclosure comprise a method of manufacturing a phase mask. In certain embodiments, the method comprises: providing a photoresist material having a first side, a second side, and a thickness; exposing the first side of the of the photoresist material to electromagnetic radiation sufficient to produce a property change in a first portion of the photoresist material; and exposing the second side of the of the photoresist material to electromagnetic radiation sufficient to produce a property change in a second portion of the photoresist material. In certain embodiments: the first portion extends from the first side to a first depth of the thickness of the photoresist material; the second portion extends from the second side to a second depth of the thickness of the photoresist material; and the first portion and the second portion overlap in an overlapping region. Specific embodiments comprise processing the photoresist material to remove the first and second portions of the photoresist material.

In certain embodiments, the photoresist material comprises a liquid crystal and a polymer. In specific embodiments, the first portion comprises linear strips that are generally parallel. The second portion can comprise linear strips that are generally parallel in certain embodiments. In certain embodiments, the first portion comprises linear strips that are generally parallel and the second portion comprises linear strips that are generally parallel and perpendicular to the linear strips of the first portion.

Certain embodiments comprise exposing the first and second side of the photoresist material to electromagnetic radiation comprises directing a laser beam towards the first and second sides. Specific embodiments comprise separating the laser beam using a beam-splitter. In specific embodiments, at least one of the first depth and the second depth is more than half of the thickness of the photoresist material. In certain embodiments, the sum of the first depth and the second depth is greater than the thickness of the photoresist material.

Exemplary embodiments of the present disclosure comprise a method of manufacturing a phase mask, comprising: providing a photoresist material comprising a liquid crystal and a photo-sensitive material, wherein the photoresist material comprises a first side and a second side; exposing the first side of the photoresist material to a first pattern of light comprising a first plurality of lighter areas and a first plurality of darker areas, exposing the second side of the photoresist material to a second pattern of light comprising a second plurality of lighter areas and a second plurality of darker areas; and exposing the photoresist material to a developer, wherein the developer removes the photoresist material in areas of the photoresist material that are exposed to the first and second pluralities of lighter areas.

In certain embodiments, the photo-sensitive material comprises a photo-sensitive monomer. In specific embodiments, the photo-resist material comprises a photo-sensitive polymer. In certain embodiments, the photo-sensitive material comprises a mixture of a photo-sensitive monomer and a photo-sensitive polymer.

Exemplary embodiments may also comprise a method of manufacturing a phase mask, comprising: providing a photoresist material comprising a liquid crystal and a photo-sensitive material, wherein the photoresist material comprises a first side and a second side; exposing the first side of the photoresist material to a first pattern of light comprising a first plurality of lighter areas and a first plurality of darker areas; exposing the second side of the photoresist material to a second pattern of light comprising a second plurality of lighter areas and a second plurality of darker areas; and exposing the photoresist material to a developer, wherein the developer removes the photoresist material in the areas of the photoresist material that are exposed to the first and second pluralities of darker areas.

Certain embodiments comprise increasing the concentration of the polymer in a portion of the first and side of the photoresist material exposed to the first and second pluralities of lighter areas. Specific embodiments comprise increasing the concentration of the liquid crystal in a portion of the first and side of the photoresist material exposed to the first plurality of darker areas.

In certain embodiments, the portion of the first side of the photoresist material exposed to the first plurality of lighter areas extends partially through the photoresist material. In specific embodiments, the portion of the first side of the photoresist material exposed to the first plurality of lighter areas extends approximately halfway through the photoresist material. In certain embodiments, the portion of the second side of the photoresist material exposed to the first plurality of lighter areas extends partially through the photoresist material. In specific embodiments, the portion of the second side of the photoresist material exposed to the first plurality of lighter areas extends approximately halfway through the photoresist material.

In certain embodiments, the photoresist material is substantially planar. In specific embodiments, the first pattern of light is produced by two overlapping laser beams. In certain embodiments, the first pattern of light is equivalent to the second pattern of light.

In specific embodiments, the first pattern of light is moved in a first direction along the first side of the photoresist material and the second pattern of light is moved in a second direction along the second side of the photoresist material. In specific embodiments, the second direction is substantially 90 degrees from the first direction.

Exemplary embodiments comprise a method of manufacturing a phase mask, comprising: providing a photoresist material comprising a liquid crystal and a photo-sensitive material; exposing a first side of the photoresist material to a pattern of light to create a first plurality of polymer-rich regions and a first plurality of liquid crystal-rich regions; exposing a second side of the photoresist material to the pattern of light to create a second plurality of polymer-rich regions and a second plurality of liquid crystal-rich regions; and removing the first and second pluralities of polymer-rich regions.

Exemplary embodiments comprise a method of manufacturing a phase mask, comprising: providing a photoresist material comprising a liquid crystal and a photo-sensitive material; exposing a first side of the photoresist material to a pattern of light to create a first plurality of polymer-rich regions and a first plurality of liquid crystal-rich regions; exposing a second side of the photoresist material to the pattern of light to create a second plurality of polymer-rich regions and a second plurality of liquid crystal-rich regions; and removing the first and second pluralities of liquid crystal-rich regions.

In certain embodiments, the first plurality of polymer-rich regions and the first plurality of liquid-crystal-rich regions form alternating linear strips. In specific embodiments, the first plurality of polymer-rich regions are substantially perpendicular to the first plurality of liquid-crystal rich regions. In certain embodiments, the first plurality of polymer-rich regions and the first plurality of liquid-crystal-rich regions extend partially through the thickness of the photoresist material. In specific embodiments, the first plurality of polymer-rich regions and the first plurality of liquid-crystal-rich regions extend more than halfway through but less than all the way through photoresist material. In certain embodiments, the photoresist material is an epoxy based material.

Exemplary embodiments comprise a two-layer, integrated phase mask comprising: a first layer of a photoresist material configured in a first pattern; a second layer of a photoresist material configured in a second pattern; and one or more apertures extending through the first and second layers of photoresist material, where the first layer and the second layer of photoresist material are formed from a unitary piece of photoresist material.

### BRIEF DESCRIPTION OF THE DRAWINGS

The following drawings illustrate by way of example and not limitation. Identical reference numbers do not necessarily indicate an identical structure. Rather, the same reference number may be used to indicate a similar feature or a feature with similar functionality, as may non-identical reference numbers. Every feature of each embodiment is not always labeled in every figure in which that embodiment appears, in order to keep the figures clear. FIGS. 1-5 are not drawn to scale.

FIG. 1 is a front perspective view of a photoresist material on a slide, according to one embodiment of the present invention.

FIG. 2 is a front perspective view of a photoresist material during production of a phase mask, according to one embodiment of the invention.

FIG. 3 is a rear perspective view of the embodiment of FIG. 2 after an additional production step has been performed.

FIG. 4 is a front perspective view of the embodiment of FIG. 3.

FIG. 5 is a front perspective view of the embodiment shown in FIG. 4 after an additional production step has been performed.

FIGS. 6(a) and 6(b) are perspective views of a photoresist material and a phase mask produced from the photoresist material.

FIGS. 7(a) and 7(b) are scanning electron microscope views of the grating structure of a phase mask.

FIG. 8(a) is a schematic of setup for single beam, single exposure fabrication of photonic crystal using the phase mask and 8(b) is a scanning electron microscope view of fabricated photonic crystal template using the phase mask.

FIGS. 9(a), 9(b), and 9(c) are top views of a five-beam interference pattern generated by the phase mask with different phase shifts, and FIG. 9(d) is a three-dimensional structure of a five-beam interference generated by the phase mask.

### DESCRIPTION OF ILLUSTRATIVE EMBODIMENTS

The terms “comprise” (and any form of comprise, such as “comprises” and “comprising”), “have” (and any form of have, such as “has” and “having”), “contain” (and any form of contain, such as “contains” and “containing”), and “include” (and any form of include, such as “includes” and “including”) are open-ended linking verbs. As a result, a device, a system or a method that “comprises,” “has,” “contains,” or “includes” one or more recited elements or steps possesses those recited elements or steps, but is not limited to possessing only those elements or steps; it may possess elements or steps that are not recited. Likewise, an element of a device, system or method that “comprises,” “has,” “contains,” or “includes” one or more recited features possesses those features, but is not limited to possessing only those features; it may possess features that are not recited. Furthermore, a structure, such as one of the present insertion devices, that is configured in a certain way must be configured in at least that way, but also may be configured in a way or ways that are not specified.

The terms “a” and “an” are defined as one or more than one unless this disclosure explicitly requires otherwise. The terms “substantially” is defined as at least close to (and includes) a given value or state (preferably within 10% of, more preferably within 1% of, and most preferably within 0.1% of). The term “coupled” is defined as connected, although not necessarily directly, and not necessarily mechanically; two items that are “coupled” may be integral with each other.

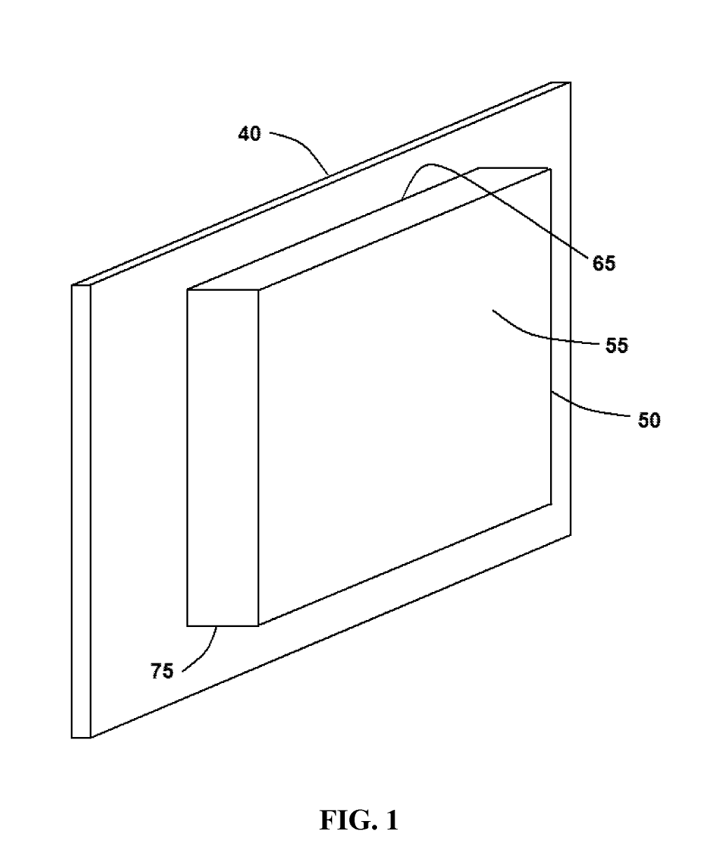

Referring initially to FIGS. 1-5, a phase mask 100 is produced by modifying a photoresist material 50 having a first side 55, a second side 65 and a thickness 75. In the embodiment shown in FIG. 1, photoresist material 50 is placed on a glass slide 40 so that second side 65 is in contact with glass slide 40. Glass side 40 is not shown in the additional figures for purpose of clarity, but it is understood that photoresist material 50 may be supported by glass side 40 (or an equivalent support) throughout the manufacturing process.

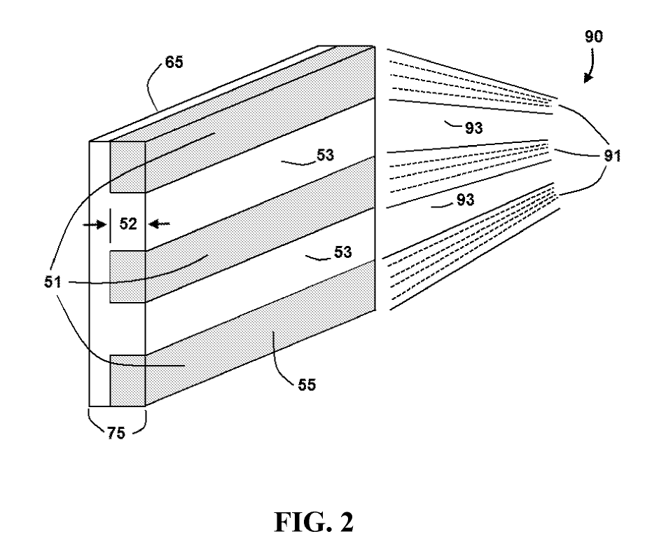

As illustrated in FIG. 2, first side 55 of photoresist material 50 is exposed to light 90 (described in more detail below) sufficient to produce a property change in an exposed portion 51 of the photoresist material. In this embodiment, exposed portion 51 of the photoresist material undergoes a property change and extends from first side 55 to a depth 52 that is less than all of the way through the thickness 75 of photoresist material 50. In exemplary embodiments, depth 52 is more than halfway through the thickness 75 of the photoresist material 50, but less than all of the way through thickness 75. The length of time that photoresist material 50 is exposed to light 90 will affect the depth 52 to which exposed portion 51 extends into photoresist material 50. Other factors will also affect depth 52, including the intensity of light 90 and the composition of photoresist material 50.

In specific embodiments, photoresist material 50 may comprise a liquid crystal and polymer mixture, and the exposure of photoresist material 50 to light (or other electromagnetic radiation) can cause the polymer molecules in exposed portion 51 to link together to force the liquid crystal into underexposed portion 53 of the photoresist material. This effectively creates a “polymer-rich” region in exposed portion 51 and a “liquid crystal-rich” region in underexposed portion 53 of the photoresist material.

In certain embodiments, the source of light 90 may be two overlapping laser beams that create lighter fringes 91 (e.g., areas that contain higher energy than darker fringes) and darker fringes 93 (e.g., areas that contain less energy than lighter fringes 91) in the overlapping beam regions. Lighter fringes 91 can be directed toward first side 55 of photoresist material 50 to create exposed portion 51, while the darker fringes 93 can be directed toward first side 55 to create underexposed portion 53. In the embodiment shown, exposed portion 51 and underexposed portion 53 form alternating linear strips on photoresist material 50.

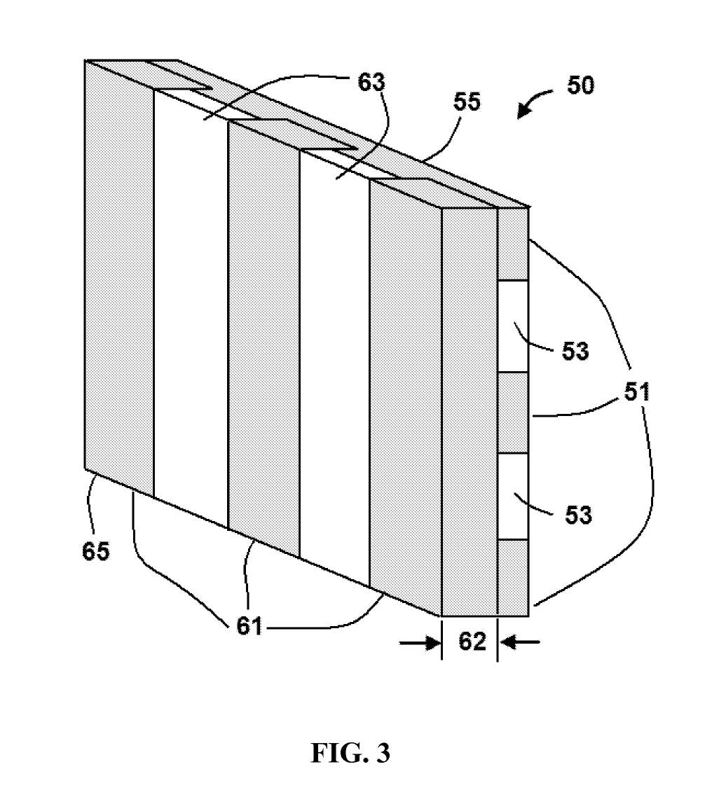

In specific embodiments, second side 65 is also exposed to light 90 in a manner generally equivalent to that provided for first side 55. In exemplary embodiments, however, photoresist material 50 can be rotated 90 degrees between the exposure of the first side 55 and the second side 65. Referring now specifically to FIG. 3, the exposure of second side 65 to light 90 (not shown, comprising lighter fringes 91 and darker fringes 93) produces exposed portions 61 and underexposed portions 63. In the embodiment shown, exposed portions 61 and underexposed portions 63 comprises alternating linear strips that are arranged orthogonally from exposed portions 51 and underexposed portions 53. Exposed portions 61 also extend partially through thickness 75 of photoresist material 50. In the embodiment shown, exposed portions 61 extend a depth 62 more than halfway through thickness 75, but less than all of the way through thickness 75. It is understood that first side 55 and second side 65 may be exposed to light 90 for different lengths of time, or that the intensity of light 90 may be different for the exposure of first side 55 and second side 65.

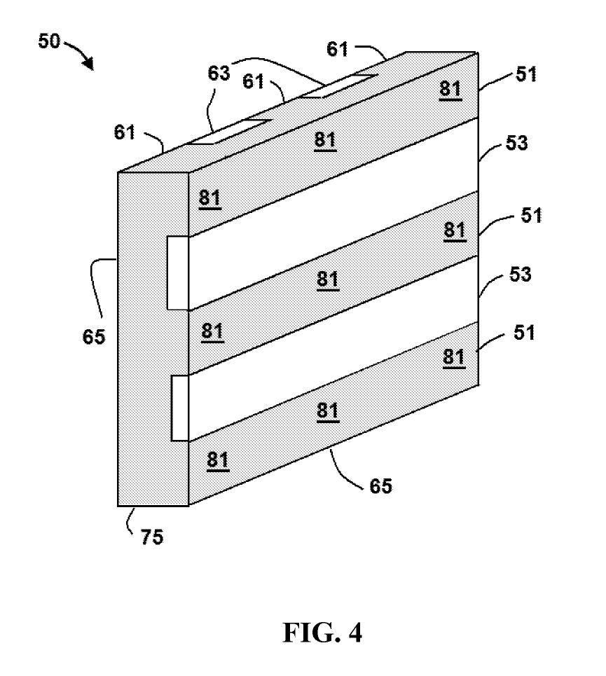

As shown in FIG. 4, exposed portions 61 and 51 overlap at overlapping portions 81 (e.g., because exposed portions 61 and 51 each extend more than half way through thickness 75 of photoresist material 50). Overlapping portions 81 therefore extend through the entire thickness 75 of photoresist material 50. It is understood that in other embodiments, exposed portions 51 and 61 may not both extend more than half way through thickness 75 of photoresist material 50. For example, exposed portion 51 may extend to a depth 52 that extends at least one-third of the thickness 75 of photoresist material. Exposed portion 61 may then extend to a depth 62 that extends at least two-thirds of the thickness 75 of photoresist material 50. In such an embodiment, the sum of depths 52 and 62 will be greater than thickness 75, and exposed portions 51 and 61 will still overlap at overlapping portions 81.

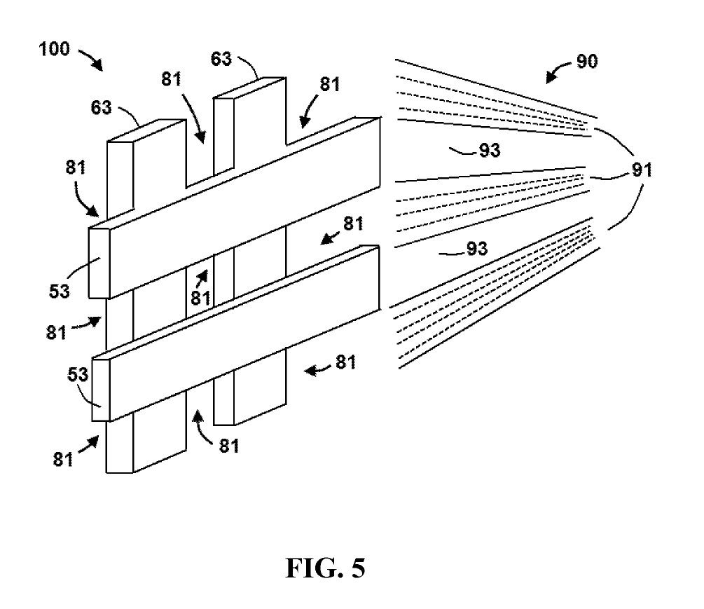

After first side 55 and second side 65 of photoresist material 50 have been exposed to light 90, photoresist material 50 may be exposed to a developer to remove exposed portions 51 and 61. Referring now specifically to FIG. 5, phase mask 100 is shown to include underexposed portions 53 and 63. In the embodiment shown, exposed portions 51 and 61 have been removed so that overlapping portions 81 create apertures that extend through the entire thickness of photoresist material 50. In the illustrated embodiment, exposed portions 51 and 61 each form sets of substantially parallel linear strips. Also visible in FIG. 5, the strips of exposed portions 51 and 61 are arranged generally orthogonal to each other. This results from the rotation of photoresist material 50 (or the rotation of the direction of light 90) between the exposure of first side 55 and second side 65 to light 90.

It is understood that in other embodiments, the angle between the strips formed in exposed portions 51 and 61 may be some angle other than 90 degrees. It is also understood that in other embodiments, the pattern of light used to expose each side of the photoresist material may not be alternating linear lighter and darker regions. Furthermore, it is understood that phase mask 100 may be fabricated from a negative resist material, rather than a positive resist material such as that used in the process described in the discussion of FIGS. 1-5. In such embodiments, the underexposed portion of the photoresist material should extend from the first side to a depth sufficient to allow it to overlap with the underexposed portion from the second side. Therefore, when the underexposed portions are removed during the development process, the overlapping portions will create apertures in the photoresist material.

The above-described method can therefore be used to fabricate a phase mask 100 that is a two-layer, integrated phase mask. As illustrated in the embodiment shown in the Figures and described herein, phase mask 100 comprises underexposed portions 53 in one layer of photoresist material 50 proximal to first side 55. Phase mask 100 also comprises underexposed portions 63 in a second layer of photoresist material 50 proximal to second side 65. The illustrated embodiment also comprises a series of apertures (formed in overlapping portions 81 of exposed portions 53 and 63 of photoresist material) that extend through the first and second layers of photoresist material 50.

### Example

One exemplary embodiment of the present technique comprised the fabrication of a single integrated optical phase mask consisting of two orthogonally oriented gratings in a photoresist as a proof of concept. One laser beam (532 nm, 60 mW, Coherent Compass laser) was expanded to a size of 10 mm and separated into two beams using a beam-splitter. A parallel fringe is formed when the two laser beams overlap. The spacing Λ between the dark (or bright) fringes is determined by the laser wavelength and interference angle θ by the relationship of Λ=λ/(2 sin θ). When a photoresist is exposed to the inference pattern and developed, it forms a one-dimensional grating on the substrate. In order to protect the grating formed after laser exposure, liquid crystal was mixed with the photoresist and a phase separation played a key role in the fabrication of integrated phase mask described as follows.

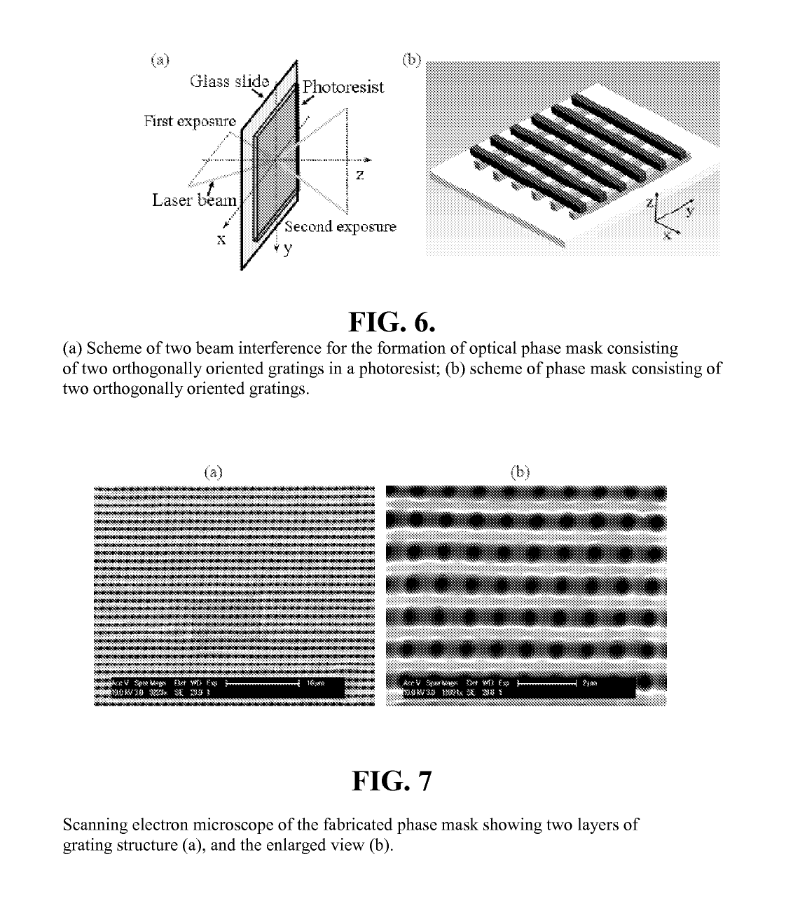

The photoresist mixtures were similar to a reported formulation (without fatty acid) [23] containing the following components in the specified weight concentrations: dipentaerythritol penta/hexaacrylate (DPHPA) monomer (Aldrich, 65%), BL111 liquid crystal (EMD Chemicals, 25%), a photo initiator rose bengal (0.3%), co-initiator N-phenyl glycine (0.5%), chain extender (N-vinyl pyrrolidinone) (9.2%). This mixture was spin coated over a transparent glass slides (Corning) with a typical speed of 4000 rpm for the phase mask fabrication. Due to a well known polymerization-induced phase separation process [23, 24], the laser-exposed sample consists of a periodic distribution of liquid crystal-rich domains, corresponding to the dark regions of the interference pattern, and polymer-rich grating structure. Two laser exposures were performed for the fabrication of phase mask. For the first exposure, two interfering laser beams came from glass slide side as shown in FIG. 6(a) and formed the liquid crystal-rich and polymer-rich gratings parallel to y-direction after first exposure (the exposure was in the range of 0.5 to 2 seconds). Because the exposure time is short, only the photoresist near the glass-slide (substrate) becomes polymerized. Then the same sample was exposed to the laser interference pattern coming from the sample side as shown in the figure. However the interference pattern is rotated by 90 degree and a grating parallel to x-direction was formed in the sample after second exposure (the exposure was in the range of 2 to 4 seconds). The sample was developed in propylenglycolmethylether acetate (PGMEA) (Microchem) for 20 seconds and rinsed in Isopropanol. The developed sample forms grating structure as schemed in FIG. 6(b).

FIG. 7(a) shows the scanning electron microscope (SEM) of the fabricated sample. The SEM shows clearly two layers of grating structures. The top layer has a grating in horizontal direction. The layer beneath has a grating in vertical direction, orthogonal to the top grating structure. FIG. 7(b) shows an enlarged view of the fabricated structure. From the scale bar, the period of the grating was measured to be 1.06 μm. The diffraction angle of the 532 nm laser by the grating was measured to be 31 degree, corresponding to a period of the grating of 1.03 μm. These two measurements indicate that the period is in the range between 1.03 and 1.06 μm. When one single beam goes through such phase mask, it is desirable to have five and only five diffracted beams behind the phase mask, namely the (0,0), (0, ±1) and (±1, 0) beams [19]. The next lowest order beams are the (±1, ±1) beams. If the phase mask was designed properly, these four beams vanish. The five low order diffracted beams can be described by:

E_{0,0}(r,t)=E_{0,0} cos((k_{0,0}·r−ωt+δ₁),

E_{1,0}(r,t)=E_{1,0} cos((k_{1,0}·r−ωt+δ₁),

E_{-1,0}(r,t)=E_{-1,0} cos((k_{-1,0}·r−ωt+δ₁),

E_{0,1}(r,t)=E_{0,1} cos((k_{0,1}·r−ωt+δ₂),

E_{0,-1}(r,t)=E_{0,-1} cos((k_{0,-1}·r−ωt+δ₂),

k and ω are the wave vector and angular frequency of the beam, respectively, E is the constant of electric field strength, and δ is the initial phase of the beam. If the initial phases for five beams are same, the generated interference pattern has face-center-cubic (FCC) or tetragonal (FCT) symmetry [17, 19, 20]. In this study, the initial phases for beams (0, 1) and (0, −1) are same, but different from these for beams (0, 0), (1, 0), and (−1, 0), i.e. the δ1 and δ2 are different in above equations. It is due to the optical path difference developed for 0th order and 1st order diffracted beams until these beams reach the second grating [19]. The beam intensities for (0, 1) and (0, −1) modes can be different from these for beams (1, 0), and (−1, 0), depending on the diffraction efficiency. Such phase mask can produce diffracted beams with different phase shift and beam intensity. The generated interference pattern behind the phase mask can be diamond or diamond-like structure [17, 19, 20].

### 3. Single-Beam, Single Exposure Fabrication of Photonic Crystal Template

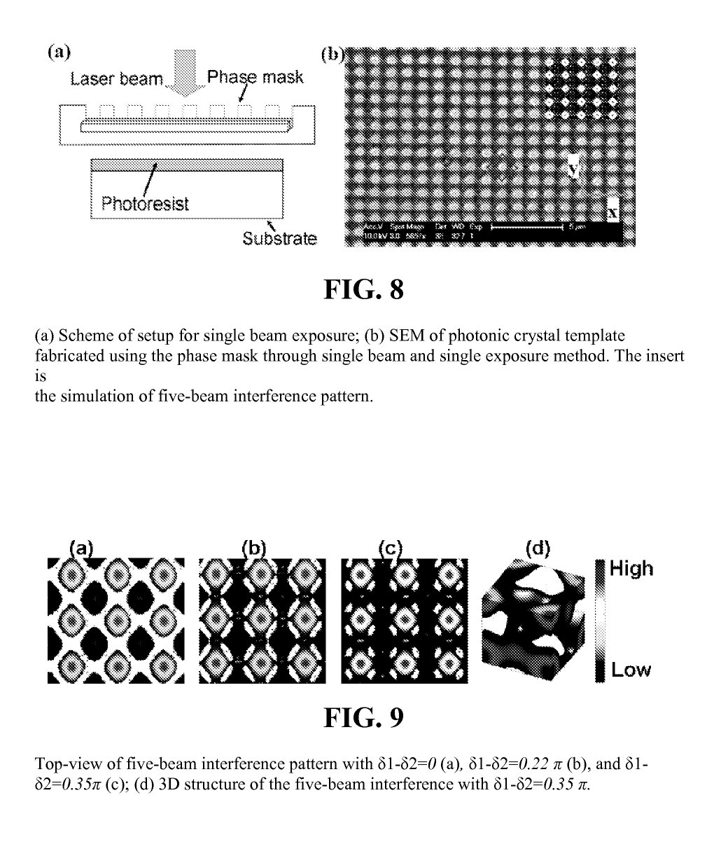

The lab-fabricated phase mask was used to generate a 3D photonic crystal template in the photoresist mixture with a similar formulation to one described above except that the liquid crystal was omitted. The mixture was spin-coated on glass slide substrate at a speed of 1000 rpm. The thickness is approximately 15 micron. The phase mask used can generate beams with an intensity ratio of 1:0.68:0.38:0.13 for (0, 0), (1, 0), (0, 1) and (1, 1), respectively. The beams (1, 0) and (−1, 0) have approximately the same intensity (beams (0, 1) and (0, −1) have the same intensity also). The (±1, ±1) beams are very weak and their diffraction angles are larger than other (±1, 0) and (0, ±1) beams. As shown in FIG. 8(a), a single beam passes through the phase mask and generates the interference pattern behind the phase mask. The sample was placed in a location where five and only five beams overlap and generate the interference pattern. One exposure is enough for the recording of photonic crystal in the photoresist. The exposure time is 60 seconds. The exposed photoresist was developed in PGMEA. FIG. 8(b) shows the SEM of the fabricated 3D photonic crystal structure. From the theory, the period in x or y directions of the structure in FIG. 8(b) should be same as grating period of the phase mask. The measured period in FIG. 8(b) is approximately 1.10 μm, compared with the measured grating period of 1.06 μm in FIG. 7(b). The fabricated structure has a diamond-like structure with a face-center-tetragonal symmetry with a top surface shown by the square in the FIG. 8(b). The structure can be simulated by the five-beam (as described by above equations) interference as shown as an insert in FIG. 8(b). The beam intensities have been chosen with the value we have measured above. A phase shift of 0.35π (δ1−δ2=0.35π) between group of (0, 1) and (0, −1) beams and group of (0, 0), (1, 0), and (−1, 0) beams has been used for the simulation, indicating the phase shift among beams generated by the phase mask.

### 4. Discussions

The described method solved the optical alignment problem that that has been faced using two separate one-dimensional phase mask [18]. During the exposure of the photo-sensitive mixture to the three-beam interference pattern for the fabrication of photonic crystal, it was not easy to align two interference patterns in 3D space to form the wood-pile type structure [18]. For the current work, since a two-beam interference is being used for the fabrication of the phase mask, there is no issue of alignment as long as the sample is rotated for 90 degree for the second exposure. The optical alignment for the fabrication of the photonic crystal using the phase mask is no longer a concern. Using a one-dimensional phase mask, two exposures of sample to the interference pattern were required to produce 3D photonic crystal [18]. Using two-dimensional phase mask, one exposure can produce 3D photonic crystal [17]. With the two-layer (3D) phase mask, not only is it possible to produce 3D photonic crystal through single beam and single exposure, but it is also possible to control the phase shift of the interfering beams. The phase shift is necessary for the fabrication of 3D photonic crystal with a large photonic band gap. FIG. 9 shows the five beam interference pattern with a different phase shift of δ1-δ2. Without the phase shift (FIG. 9(a)), the motif of the structure is simple and the lattice has FCT symmetry. When increasing the phase shift from zero to 0.22π, two spheres in the lattice started to interconnect together (FIG. 9(b)). The top-view of the interference pattern with δ1−δ2=0.35π looks like wood-pile-type structure (FIG. 9(c)). FIG. 9(d) shows 3D structure of the same interference pattern showing interconnected motif, similar to the isointensity surface shown in FIG. 2 of reference 19.

Once the optimal directions, amplitudes, polarizations, and phases are determined, a two-layer phase mask can be designed and fabricated to yield the optimal diffraction condition for the holographic fabrication. The integration of the two-layer phase mask on a single substrate represents a significant improvement toward mass production of 3D photonic structures. Since the two-layer mask can be readily integrated with multiple-layer amplitude mask based IC fabrication, the proposed approaches also provide an avenue for chip-scale integration of the 3D photonic devices with other lightwave and electronic circuit elements.

### 5. Summary

In summary, the fabrication of two-layer integrated phase mask consisting of two orthogonally oriented gratings has been demonstrated experimentally. The phase mask is made by double exposure of the photoresist to the laser interference pattern. The phase separation between liquid crystal and polymer helps preserve the grating produced in the first exposure. The phase relation among the diffracted beams from the phase mask can be manipulated for the generation of photonic crystal with a large photonic band gap. The photonic crystal template has been fabricated by single-exposure, single-beam, optical interference lithography through the single integrated phase mask.

### REFERENCES

The following references are herein incorporated by reference:
U.S. Pat. No. Re. 36,113
U.S. Pat. No. 5,753,417
U.S. Pat. No. 6,333,129
U.S. Pat. No. 6,645,603
U.S. Pat. No. 7,324,280
U.S. Pat. No. 5,753,417
U.S. Patent Publication No. 2008/0036986
U.S. Patent Publication No. 2008/0286488
Berger et al., J. Appl. Phys., 82:60-64, 1997.
Blanco et al., Nature (London), 405:437-440, 2000.
Campbell et al., Nature (London), 404:53-56, 2000.
Chan et al., Phys. Rev. E, 73:046610/1-11, 2006.
Deubel et al., Nat. Mater., 3:444-447, 2004.
Divliansky et al., Appl. Phys. Lett., 82:1667-1669, 2003.
Escuti et al., Opt. Lett., 28:522-524, 2003.
Ho et al., Solid State Commun., 89:413-416, 1994.
Jakubiak et al., Appl. Phys. Lett., 85:6095-6097, 2004.
Jeon et al., Proc. Natl. Acad. Sci. USA, 101:12429-12434, 2004.
Joannopoulos et al., Nature (London), 386:143-147, 1997.
John, Phys. Rev. Lett., 58:2486-2489, 1987.
Lai et al., Opt. Express, 13:9605-9611, 2005.
Lin et al., Appl. Phys. Lett., 86:071117/1-3, 2005.
Lin et al., Applied Optics, 45:7971-7976, 2006.
Lin et al., J. Appl. Phys., 97:096102/1-3, 2005.
Miguez et al., Chem. Commun. (Cambridge), 22:2736-2737, 2002.
Pang et al., Opt. Express, 13:7615-7620, 2005.
Sharp et al., Phys. Rev. B, 68:205102-6, 2003.
Tereault et al., Adv. Mater., 18:457-460, 2006.
Toader et al., Phys. Rev. Lett., 92:043905/1-4, 2004.
Tondiglia et al., Adv. Mater., 14:187-191, 2002.
Yablonovitch, Phys. Rev. Lett., 58:2059-2062, 1987.
Yang et al., Chem. Mater., 14:2831-2833, 2002.

1. A method of manufacturing a phase mask, the method comprising:
providing a photoresist material having a first side, a second side, and a thickness;
exposing the first side of the of the photoresist material to electromagnetic radiation sufficient to produce a property change in a first portion of the photoresist material;
exposing the second side of the of the photoresist material to electromagnetic radiation sufficient to produce a property change in a second portion of the photoresist material, wherein:
the first portion extends from the first side to a first depth of the thickness of the photoresist material;
the second portion extends from the second side to a second depth of the thickness of the photoresist material; and
the first portion and the second portion overlap in an overlapping region; and
processing the photoresist material to remove the first and second portions of the photoresist material.

2. The method of claim 1, wherein the photoresist material comprises a liquid crystal and a polymer.

3. The method of claim 1, wherein the first portion comprises linear strips that are generally parallel.

4. The method of claim 1, wherein the second portion comprises linear strips that are generally parallel.

5. The method of claim 1, wherein the first portion comprises linear strips that are generally parallel and the second portion comprises linear strips that are generally parallel and perpendicular to the linear strips of the first portion.

6. The method of claim 6, wherein exposing the first and second side of the photoresist material to electromagnetic radiation comprises directing a laser beam towards the first and second sides.

7. The method of claim 6, further comprising separating the laser beam using a beam-splitter.

8. The method of claim 1, wherein at least one of the first depth and the second depth is more than half of the thickness of the photoresist material.

9. The method of claim 1, wherein the sum of the first depth and the second depth is greater than the thickness of the photoresist material.

10. A method of manufacturing a phase mask, the method comprising:
providing a photoresist material comprising a liquid crystal and a photo-sensitive material, wherein the photoresist material comprises a first side and a second side;
exposing the first side of the photoresist material to a first pattern of light comprising a first plurality of lighter areas and a first plurality of darker areas,
exposing the second side of the photoresist material to a second pattern of light comprising a second plurality of lighter areas and a second plurality of darker areas; and
exposing the photoresist material to a developer, wherein the developer removes the photoresist material in areas of the photoresist material that are exposed to the first and second pluralities of lighter areas.

11. The method of claim 10, wherein the photo-sensitive material comprises a photo-sensitive monomer.

12. The method of claim 10, wherein the photo-resist material comprises a photo-sensitive polymer.

13. The method of claim 10, wherein the photo-sensitive material comprises a mixture of a photo-sensitive monomer and a photo-sensitive polymer.

14. A method of manufacturing a phase mask, the method comprising:
providing a photoresist material comprising a liquid crystal and a photo-sensitive material, wherein the photoresist material comprises a first side and a second side;
exposing the first side of the photoresist material to a first pattern of light comprising a first plurality of lighter areas and a first plurality of darker areas;
exposing the second side of the photoresist material to a second pattern of light comprising a second plurality of lighter areas and a second plurality of darker areas; and
exposing the photoresist material to a developer, wherein the developer removes the photoresist material in the areas of the photoresist material that are exposed to the first and second pluralities of darker areas.

15. The method of claim 14, wherein the photo-sensitive material comprises a photo-sensitive monomer.

16. The method of claim 14, wherein the photo-resist material comprises a photo-sensitive polymer.

17. The method of claim 14, wherein the photo-sensitive material comprises a mixture of a photo-sensitive monomer and a photo-sensitive polymer.

18. The method of claim 10 or 14, further comprising increasing the concentration of the polymer in a portion of the first and side of the photoresist material exposed to the first and second pluralities of lighter areas.

19. The method of claim 10 or 14, further comprising increasing the concentration of the liquid crystal in a portion of the first and side of the photoresist material exposed to the first plurality of darker areas.

20. The method of claim 10 or 14, wherein the portion of the first side of the photoresist material exposed to the first plurality of lighter areas extends partially through the photoresist material.

21. The method of claim 10 or 14, wherein the portion of the first side of the photoresist material exposed to the first plurality of lighter areas extends approximately halfway through the photoresist material.

22. The method of claim 10 or 14, wherein the portion of the second side of the photoresist material exposed to the first plurality of lighter areas extends partially through the photoresist material.

23. The method of claim 10 or 14, wherein the portion of the second side of the photoresist material exposed to the first plurality of lighter areas extends approximately halfway through the photoresist material.

24. The method of claim 10 or 14, wherein the photoresist material is substantially planar.

25. The method of claim 10 or 14, wherein the first pattern of light is produced by two overlapping laser beams.

26. The method of claim 10 or 14, wherein the first pattern of light is equivalent to the second pattern of light.

27. The method of claim 10 or 14, wherein the first pattern of light is moved in a first direction along the first side of the photoresist material and wherein the second pattern of light is moved in a second direction along the second side of the photoresist material.

28. The method of claim 10 or 14, wherein the second direction is substantially 90 degrees from the first direction.

29.-41. (canceled)

42. A two-layer, integrated phase mask comprising:
a first layer of a photoresist material configured in a first pattern;
a second layer of a photoresist material configured in a second pattern; and
one or more apertures extending through the first and second layers of photoresist material, wherein the first layer and the second layer of photoresist material are formed from a unitary piece of photoresist material.
